(19) United States
(12) Patent Application Publication
(10) Pub. No.: US 2008/0296770 A1
(43) Pub. Date: Dec. 4, 2008

(54) Semiconductor device

(75) Inventors: Hidetomo Nishimura, Miyagi (JP); Katsutoshi Saeki, Miyagi (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/153,648

(22) Filed: May 22, 2008

(30) Foreign Application Priority Data
May 29, 2007 (JP) 2007-141372

(51) Int. Cl. H01L 23/48

(52) U.S. Cl. 257/751; 257/E29.128

(57) ABSTRACT

A semiconductor device of the present invention includes a semiconductor substrate; a diffusion layer formed about a surface of the semiconductor substrate; a first conductive layer formed on the semiconductor substrate, and an insulating layer formed on the semiconductor substrate after the first conductive layer and the diffusion layer are formed, and a second conductive layer formed on the insulating layer, and a first contact formed in the insulating layer, connecting the first conductive layer to the second conductive layer, and a second contact formed in the insulating layer, connecting the first conductive layer to the diffusion layer. In addition, a part of the diffusion layer extends to a lower portion of the first contact.

### CROSS REFERENCE TO RELATED APPLICATION

This application claims the priority of Application No. 2007-141372, filed May 29, 2007 in Japan, the subject matter of which is incorporated herein by reference.

### TECHNICAL FIELD OF THE INVENTION

The present invention relates to a semiconductor device and method for fabricating the same. In particular, the present invention relates to a configuration of a contact aperture and a diffusion layer of a semiconductor memory device, and a method for fabricating the same.

### BACKGROUND OF THE INVENTION

FIG. 1 is a plan view illustrating a part of a conventional semiconductor memory device. FIG. 2A is a cross-sectional view along the line A-A of FIG. 1. FIG. 2B is a cross-sectional view along the line B-B of FIG. 1. Contacts 103 and 104 are formed in locations accessible to a cell block 105 to provide electrical connection to a WL (word line) inside a cell of an integrated circuit of a memory device.

A first conductor 101 (WL: usually using the configuration of a laminate of a refractory metal silicide and polysilicon) extending from the cell block 105 is connected to a second conductor 102 (usually using of Al or W) by the contact 103. According to this kind of configuration, application of an electrical potential to the second conductor 102 controls an electrical potential of the first conductor 101 (WL) of the cell.

Also, the contact 104, formed simultaneously with the contact 103, connects the second conductor 102 to an N-type diffusion layer 106. The N-type diffusion layer 106 is used to prevent charge up (static buildup). In the case of a high electrical potential exceeding the withstand pressure of the N-type diffusion layer 106 and a P-type silicon substrate 109 during fabrication, the charged electrical charge in the second conductor 102 flows through the N-type diffusion layer 106. In other words, in the absence of the N-type diffusion layer 106, excessive charge in the second conductor 102 during fabrication would cause insulation breakdown of a gate insulating film under the first conductor 101. The second contact 104 connects the second conductor 102 to the N-type diffusion layer 106, thereby allowing the excessive charge in the second conductor 102 to flow as current through the N-type diffusion layer 106 to prevent insulation breakdown of the gate insulating film under the first conductor 101.

The figures illustrate a field oxide film 107. The field oxide film 107 is used to electrically separate the N-type diffusion layer 106 from other elements (such as the cell block 105).

However, miniaturization of integrated circuits in recent years has led to smaller pitches between the first conductors 101 extending from the cell block 105 and smaller widths of the first conductor 101 illustrated in FIG. 1. At this time, in the event that the contact 103 is formed out of alignment from the frst conductor 101 due to the variation of the photolithography step, the contact 103 protrudes further out than the first conductor 101, and connects with the silicon substrate 109, as illustrated in FIG. 2B. As a result, this causes a problem in which the connection decreases the yield of the semiconductor device.

Also, the field oxide film 107 of a region where contact 103 is formed for connecting the first conductor 101 and the second conductor 102, and the N-type diffusion layer 106 of a region where contact 104 is formed for connecting the second conductor 102 and the N-type diffusion layer 106 must each be formed separately. Due to this, the chip size becomes larger and there is a problem of the cost per chip increasing.

Further, because the first conductor 101 is not connected to the N-type diffusion layer 106 to prevent charge up until the second conductor 102 is formed, the charge up prior to the step forming the second conductor 102 cannot be prevented.

Patent documents 1 and 2 disclose technology forming a diffusion layer on a substrate surface under a contact, the diffusion layer having a different conduction type than that of the substrate.

[Patent document 1] Patent Laid Open No. H05-206293 official gazette

[Patent document 2] Patent Laid Open No. H01-313959 official gazette

### OBJECTS OF THE INVENTION

In consideration of the situation recited above, a first objective of the present invention is to provide: a semiconductor device preventing electrical connection through a contact hole to a silicon substrate, even in the case of the contact hole being shifted from a conductor due to factors such as miniaturization of the integrated circuit; and a method for fabricating the same.

A second objective of the present invention is to provide a semiconductor device allowing a smaller chip size, and a method for fabricating the same.

A third objective of the present invention is to provide a semiconductor device preventing charge up during a larger number of fabrication steps, and a method for fabricating the same.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention as set forth in claim 1, a semiconductor device comprises: a semiconductor substrate; a diffusion layer formed about a surface of the semiconductor substrate; a first conductive layer formed on the semiconductor substrate; an insulating layer formed on the semiconductor substrate after the first conductive layer and the diffusion layer are formed; a second conductive layer formed on the insulating layer; a first contact formed in the insulating layer, connecting the first conductive layer and the second conductive layer; and a second contact formed in the insulating layer, connecting the first conductive layer and the diffusion layer. A part of the diffusion layer extends to a lower portion of the first contact.

According to a second aspect of the present invention, a semiconductor device comprises: a semiconductor substrate; a diffusion layer formed about a surface of the semiconductor substrate; a first conductive layer formed on the semiconductor substrate; an insulating layer formed on the semiconductor substrate after the first conductive layer and the diffusion layer are formed; a second conductive layer formed on the insulating layer; and a contact formed in the insulating layer, connecting the first conductive layer to the second conductive layer and also connecting the second conductive layer to the diffusion layer.

The semiconductor device according to the second aspect of the present invention may include: a cell region having a predetermined function; and an device isolating region formed about a surface of the semiconductor substrate. Preferably in such a case, the device isolating region insulates the diffusion layer from the cell region, and the first conductive layer extends from the cell region across the device isolating region.

In a semiconductor device according to the first and the second aspect of the present invention, a first contact extends no further than a diffusion layer and does not connect to a silicon substrate even in the case of the first contact being formed out of alignment from a first conductive layer.

Also, in a semiconductor device according to the first aspect of the present invention, because a shared diffusion layer is formed under a first contact and a second contact, a smaller minimal surface area is made, and miniaturization of the chip size can be done. In a semiconductor device according to the second aspect of the present invention, a second contact can be omitted, and due to a single contact sharing (combining) the first contact and the second contact, a further reduction of surface area is possible.

According to a third aspect of the present invention, a method for fabricating a semiconductor device includes the steps of: forming a diffusion layer of a second conduction type about a surface of a semiconductor substrate of a first conduction type; forming a first conductive layer on the semiconductor substrate, wherein at least a part of the first conductive layer and the diffusion layer overlap; forming an insulating layer on the semiconductor substrate after forming the first conductive layer and the diffusion layer; forming a first contact extending to the first conductive layer in the insulating layer; forming a second contact extending to the diffusion layer in the insulating layer; and forming a second conductive layer connecting to the first contact and the second contact.

In the method for fabricating a semiconductor device according to the third aspect, the semiconductor device may have a cell region including a predetermined function; and an device isolating region formed about a surface of the semiconductor substrate. Preferably in such a case, the device isolating region insulates the diffusion layer from the cell region, and the first conductive layer extends from the cell region across the device isolating region.

According to a fourth aspect of the present invention as set forth in claim 8, a method for fabricating a semiconductor device includes the steps of: forming a diffusion layer of a second conduction type about a surface of a semiconductor substrate of a first conduction type; and forming a first conductive layer on the semiconductor substrate, wherein at least a part of the first conductive layer and the diffusion layer overlap; and forming an insulating layer on the semiconductor substrate after forming the first conductive layer and the diffusion layer; and forming a contact extending to the first conductive layer and the diffusion layer in the insulating layer; and forming a second conductive layer on the insulating layer, connecting to the contact. In addition, the diameter of the contact is set larger than the width of the first conductive layer.

In the method for fabricating a semiconductor device according to the fourth aspect, preferably the diameter of the contact is more than 5/3 in regards to the width of the first conductive layer.

In addition to the advantages of semiconductor devices according to the first and the second aspects recited above, in the methods for fabricating a semiconductor device according to the third and the fourth aspects of the present invention, because a first conductive layer inherently is connected to a diffusion layer when formed, effectively preventing charge up, the charge up prior to a step forming a second conductive layer can be efficiently prevented.

### BRIEF DESCRIPTION OF THE DRAWINGS

FIG. 1 is a plan view illustrating a part of a conventional semiconductor memory device.

FIG. 2A is a cross-sectional view along the A-A line in FIG. 1.

FIG. 2B is a cross-sectional view along the B-B line in FIG. 1.

FIG. 3 is a plan view illustrating a part of a semiconductor memory device according to a first preferred embodiment of the present invention.

FIG. 4A is a cross-sectional view along the A-A line in FIG. 3.

FIG. 4B is a cross-sectional view along the B-B line in FIG. 3.

FIGS. 5A, 5B, 6A, and 6B are cross-sectional views illustrating selected steps for fabricating a semiconductor memory device according to a first preferred embodiment of the present invention.

FIGS. 7A, 7B, 8A, and 8B are cross-sectional views illustrating selected steps for fabricating the semiconductor memory device according to the first preferred embodiment of the present invention.

FIG. 9 is a plan view illustrating a part of a semiconductor memory device according to a second preferred embodiment of the present invention.

FIG. 10A is a cross-sectional view along the A-A line in FIG. 9.

FIG. 10B is a cross-sectional view along the B-B line in FIG. 9.

FIGS. 11A, 11B, 12A, and 12B are cross-sectional views illustrating selected steps for fabricating the semiconductor memory device according to the second preferred embodiment of the present invention.

FIGS. 13A, 13B, 14A, and 14B are cross-sectional views illustrating selected steps for fabricating the semiconductor memory device according to the second preferred embodiment of the present invention.

### DESCRIPTION OF THE REFERENCE NUMERALS

201: FIRST CONDUCTIVE LAYER

202: SECOND CONDUCTIVE LAYER

203: FIRST CONTACT

204: SECOND CONTACT

206: N-TYPE DIFFUSION LAYER

209: P-TYPE SILICON SUBSTRATE

301: FIRST CONDUCTIVE LAYER

302: SECOND CONDUCTIVE LAYER

303: CONTACT

306: N-TYPE DIFFUSION LAYER

309: P-TYPE SILICON SUBSTRATE

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

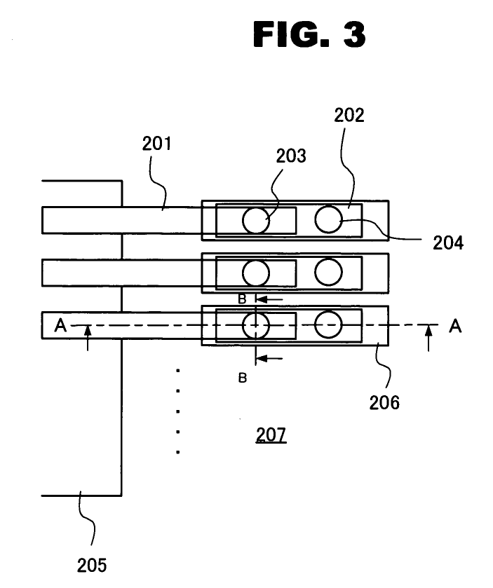

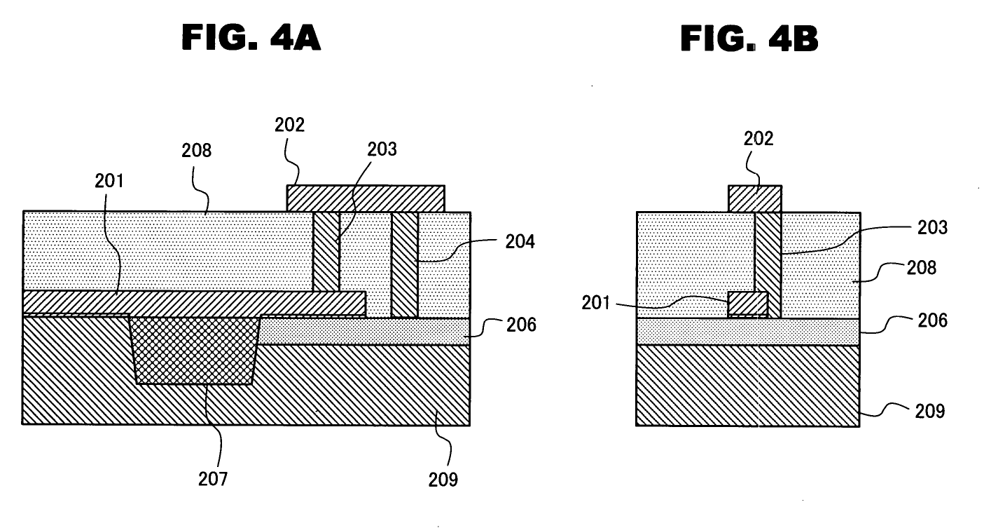

FIG. 3 is a plan view illustrating a part of a semiconductor memory device according to a first preferred embodiment of the present invention. FIG. 4A is a cross-sectional view along the A-A line in FIG. 3. FIG. 4B is a cross-sectional view along the B-B line in FIG. 3. According to this embodiment, contacts 203 and 204 are formed in locations accessible to a cell block 205 to provide connection to a WL (word line) inside a cell of an integrated circuit

A first conductor 201 (WL: usually using the configuration of a laminate of a refractory metal silicide and polysilicon) extending from the cell block 205 is connected to a second conductor 202 (usually using Al or W) by the contact 203. According to this kind of configuration, application of an electrical potential to the second conductor 202 controls an electrical potential of the first conductor 201 (WL) of the cell.

Also, the contact 204, formed simultaneously with the contact 203, connects the second conductor 202 to an N-type diffusion layer 206. The N-type diffusion layer 206 is used to prevent charge up (static buildup). In the case of a high electrical potential exceeding the withstand presure of the N-type diffusion layer 206 and a P-type silicon substrate 209 during fabrication, the charged electrical charge in the second conductor 202 flows through the N-type diffusion layer 206.

In the absence of the N-type diffusion layer 206, excessive charge in the second conductor 202 during fabrication would cause insulation breakdown of a gate insulating film under the first conductor 201. A second contact hole 204 connects the second conductor 202 to the N-type diffusion layer 206, thereby allowing the excessive charge in the second conductor 202 to flow as current through the N-type diffusion layer 206 to prevent insulation breakdown of the gate insulating film under the first conductor 201. The figures illustrate a field oxide film 207. The field oxide film 207 s used to electrically separate the N-type diffusion layer 206 from other elements (such as the cell block 105).

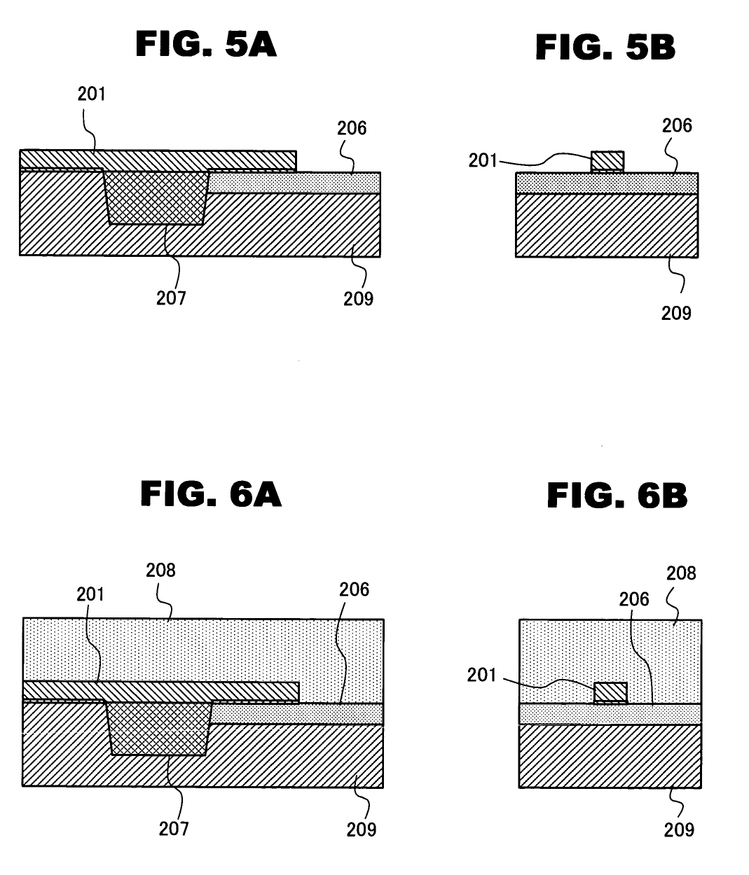

FIGS. 5A, 5B, 6A, and 6B are cross-sectional views illustrating selected steps for fabricating a semiconductor memory device according to the first embodiment of the present invention. The steps for fabricating the semiconductor memory device according to this embodiment are described below with reference to FIGS. 4A, 4B, 5A, 5B, 6A, and 6B. Regarding FIGS. 5A, 5B, 6A, and 6B, the figures on the left (A) correspond to the cross section in FIG. 4A, and the figures on the right (B) correspond to the cross section in FIG. 4B.

First, a substrate is prepared as illustrated in FIG. 5A and FIG. 5B. A field oxide film 207 and an N-type diffusion layer 206 are formed about a surface of a P-type semiconductor substrate 209 as illustrated in FIG. 5A and FIG. 5B. A gate insulating film is formed on the surface of the P-type semiconductor substrate 209, and a first conductive layer 201 is formed thereupon. Here, the N-type diffusion layer 206 is formed as to extend sufficiently under the first conductive layer 201. This extension arranges the N-type diffusion layer 206 under a first contact 203 formed subsequently.

Then, an insulating layer 208 is formed to cover the first conductive layer 201 as illustrated in FIG. 6A and FIG. 6B.

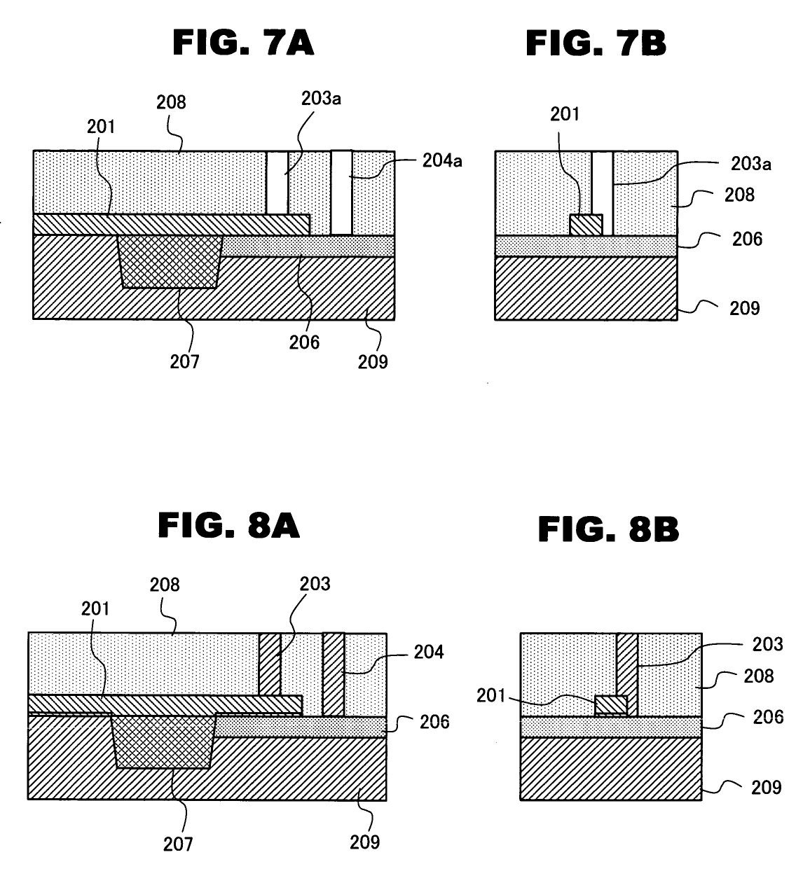

Thereafter, photolithography/etching steps form holes 203a and 204a in the insulating layer 208 for forming contacts as illustrated in FIG. 7A and FIG. 7B. Here, the hole 203a corresponding to the first contact 203, is disposed at an upper portion of the N-type diffusion layer 206, and extends to the first conductive layer 201. On the other the hole 204a, corresponding to a second contact 204, is disposed away from the first conductive layer 201, and extends to the N-type diffusion layer 206.

Then, the first contact 203 and the second contact 204 are formed by the CMP step, after tungsten (W) is deposited on the inner part of the contact holes 203a and 204a by the CVD step, as illustrated in FIG. 8A and FIG. 8B.

Then, a second conductive layer 202 is formed on an insulating layer 208 as illustrated in FIG. 4. Here, the second conductive layer 202, disposed at an upper portion of the first contact 203 and the second contact 204, electrically connects to these contacts 203 and 204. Thus, the second conductive layer 202 connects to the first conductive layer 201 through the first contact 203 and also connects to the N-type diffusion layer 206 through the second contact 204. These steps may be repeated similarly in the case of forming additional circuitry layers on the second conductive layer 202.

The first contact 203 of this embodiment extends no further than the N-type diffusion layer 206 and does not connect with the silicon substrate 209 even in the case of the first contact 203 being formed out of alignment from the first conductive layer 201.

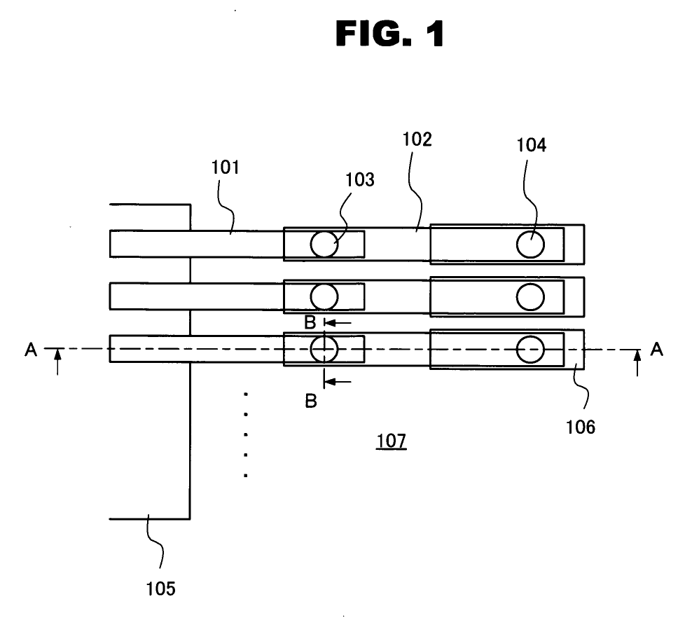

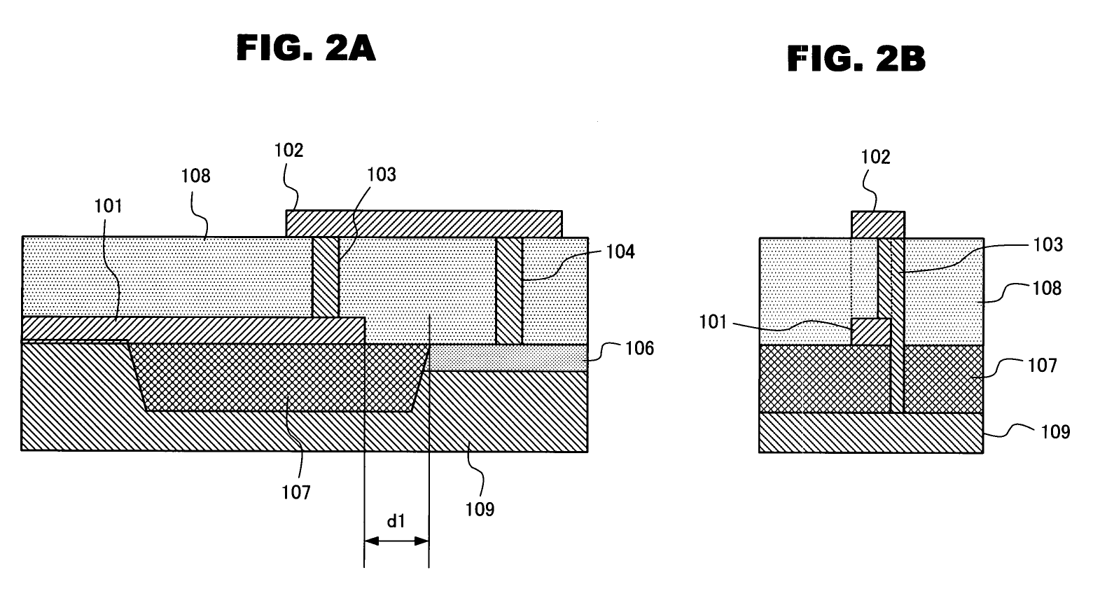

Also, because the shared (same) N-type diffusion layer 206 is formed under both the first contact 203 and the second contact 204, a smaller minimal surface area is made and miniaturization of the chip size can be done. In other words, the distance dl can be made smaller than that of the conventional configuration illustrated in FIG. 1 and FIG. 2.

Further, because the first conductive layer 201 is inherently connected to the charge up prevention N-type diffusion layer 206 when formed, the charge up prior to the step forming the second conductive layer 202 can be prevented. Conventionally, because the first conductive layer is connected to the charge up prevention N-type diffusion layer for the first time at the point when the second conductive layer is formed, the charge up step prior to forming a second conductive layer can not be prevented.

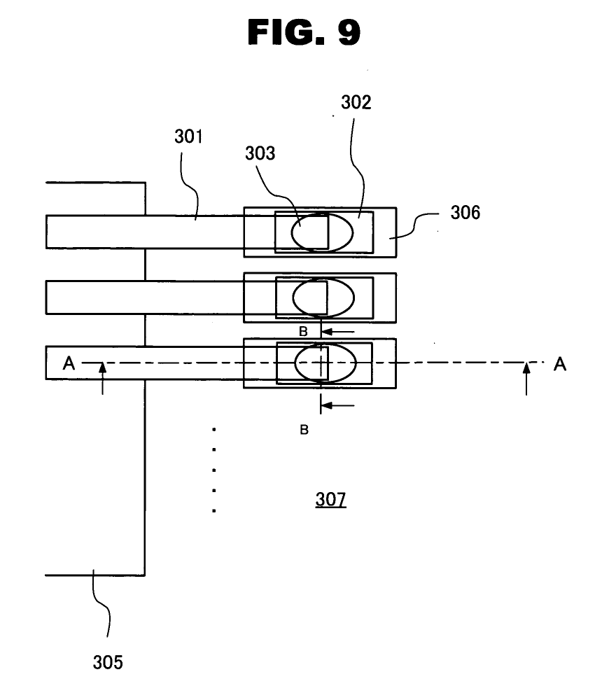

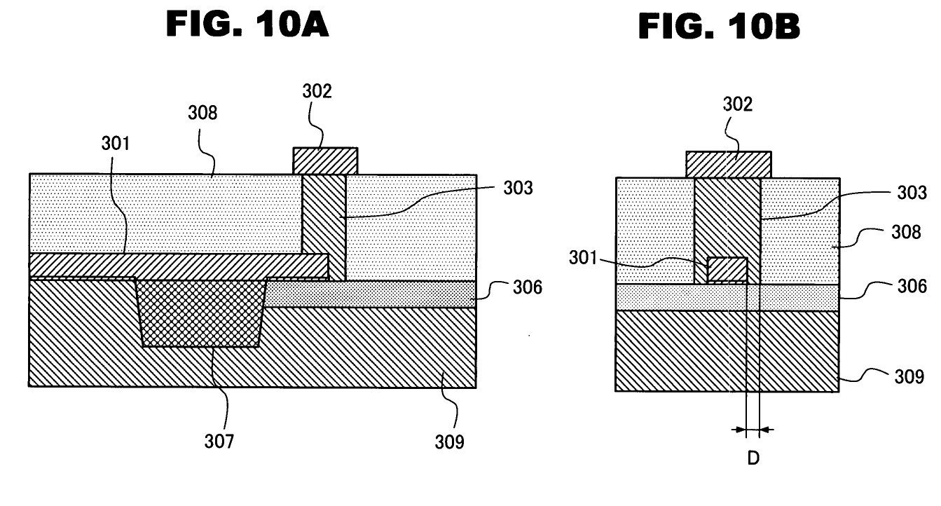

FIG. 9 is a plan view illustrating a part of a semiconductor memory device according to a second embodiment of the present invention. FIG. 10A is a cross-sectional view along the A-A line in FIG. 9. FIG. 10B is a cross-sectional view along the B-B line in FIG. 9. A contact 303 is formed in a location accessible to a cell block 305 to provide connection to a WL (word line) inside a cell of an integrated circuit according to this embodiment.

A first conductor 301 (WL: usually using the configuration of a laminate of a refractory metal silicide and polysilicon) extending from the cell block 305 is connected to a second conductor 302 (usually using Al and W) by the contact 303. According to this kind of configuration, application of an electrical potential to the second conductor 302 controls an electrical potential of the first conductor 301 (WL) of the cell.

In addition, the contact 303 connects the second conductive layer 302 to an N-type diffusion layer 306 to prevent charge up (static buildup). In the case of a high electrical potential exceeding the withstand pressure of the N-type diffusion layer 306 and a P-type silicon substrate 309 during fabrication, the charged electrical charge in the second conductor 302 flows through the N-type diffusion layer 306. In the absence of the N-type diffusion layer 306, excessive charge in the second conductor 302 during fabrication would cause insulation breakdown of a gate insulating film under the first conductor 301. The contact 303 connects the second conductor 302 to the N-type diffusion layer 306, thereby allowing the excessive charge in the second conductor 302 to flow as current through the N-type diffusion layer 306 to prevent insulator breakdown of the gate insulating film under the first conductor 301.

The figures illustrate a field oxide film 307. The field oxide film 307 is used to electrically separate the N-type diffusion layer 306 from other elements (such as the cell block 105).

The contact 303, connecting the first conductive layer 301 and the second conductive layer 302, has a diameter formed only D larger than a width of the first conductive layer 301 in this embodiment as illustrated in FIG. 10B. Due to this, the contact 303 becomes a shape overhanging beyond the first conductive layer 301. Moreover, the horizontal cross section of the contact 303 need not be circular, and may be elliptical or another shape.

Also, the direction of the overhang of the contact 303 beyond the first conductive layer 301 may be on both sides or on one side. The N-type diffusion layer 306 is disposed directly under the contact 303, thereby allowing the contact 303 to simultaneously connect to both the first conductive layer 301 and the N-type diffusion layer 306. At this time, the overlap amount D, of the contact 303 and the N-type diffusion layer 306, is more than the value of the out of alignment part of the photolithography and the connect part of the contact 303 and the N-type diffusion layer, added together. For example, the diameter of the contact 303 may be 5/3 or more of the width of the first conductive layer 301 (the circuitry width).

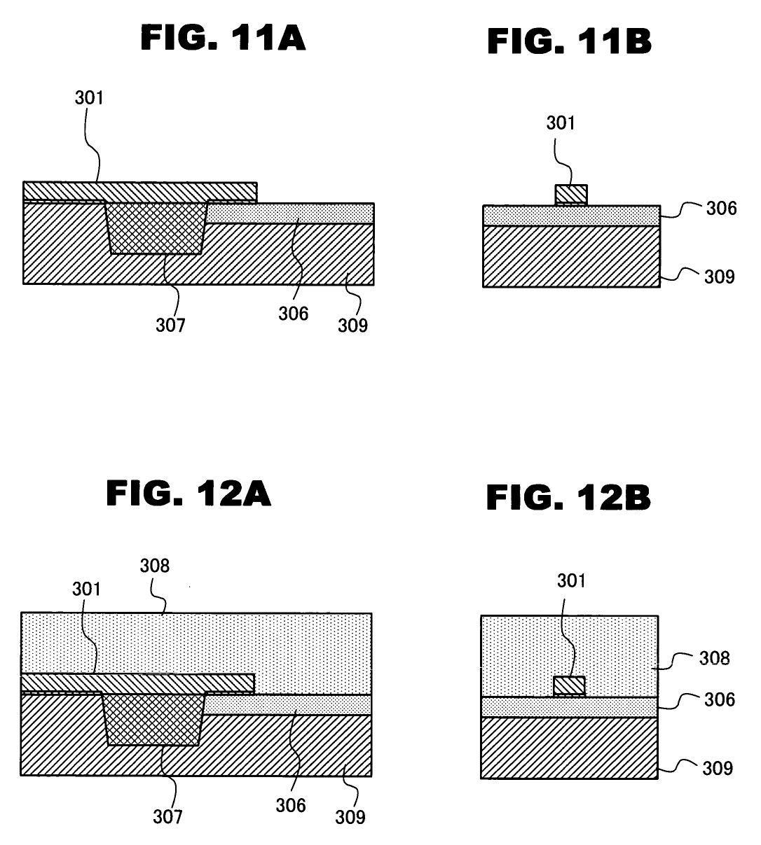

FIGS. 11A, 11B, 12A, 12B, 13A, 13B, 14A, and 14B are cross-sectional views illustrating selected steps for fabricating a semiconductor memory device according to the second embodiment of the present invention. Hereinafter, the steps for fabricating the semiconductor memory device according to this embodiment are described below with reference to these figures. Regarding FIGS. 11A to 14B, the figures on the left (A) correspond to the cross section in FIG. 10A, and the figures on the right (B) correspond to the cross section in FIG. 10B.

First, a substrate is prepared as illustrated in FIG. 11A and FIG. 11B. A field oxide film 307 and an N-type diffusion layer 306 are formed about a surface of a P-type semiconductor substrate 309 as illustrated in FIG. 11A and FIG. 11B. A gate insulating film is formed on the surface of the P-type semiconductor substrate 309, and a first conductive layer 301 is formed thereupon. Here, the N-type diffusion layer 306 is formed as to extend sufficiently under the first conductive layer 301. This extension arranges the N-type diffusion layer 306 under a contact 303 formed subsequently.

Then, an insulating layer 308 is formed to cover the first conductive layer 301 as illustrated in FIG. 12A and FIG. 12B.

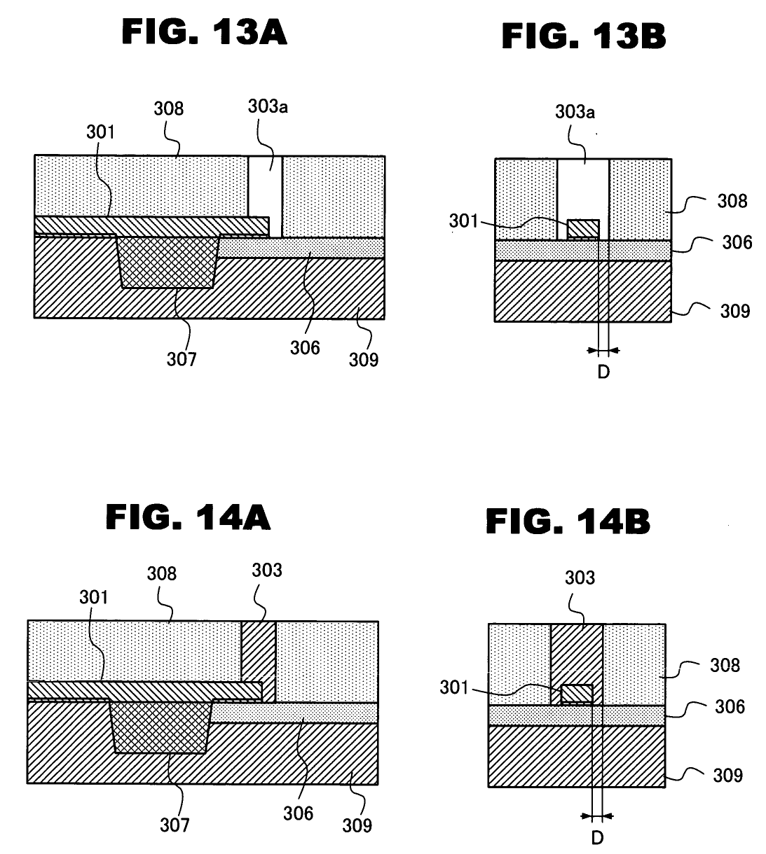

Thereafter, photolithography/etching steps form a hole 303a, in the insulating layer 308 for forming a contact as illustrated in FIG. 13A and FIG. 13B. The hole 303a corresponding to the contact 303 extends to both the first conductive layer 301 and the N-type diffusion layer 306. As stated above, the overlap amount D of the contact 303 onto the N-type diffusion layer 306 is designed, for example, such that the diameter of the contact 303 is 5/3 or more of the width of the first conductive layer 301 (the circuitry width).

Next, the contact 303 is formed by the CMP step, after tungsten (W) is deposited on the inner part of the contact hole 303a by the CVD step, as illustrated in FIG. 14A and FIG. 14B.

Then, a second conductive layer 302 is formed on the insulating layer 308 as illustrated in FIG. 10. Here, the second conductive layer 302, disposed at an upper portion of the contact 303, electrically connects to the contact 303. Thus, the second conductive layer 302 connects to both the first conductive layer 301 and also connects the N-type diffusion layer 306 through the contact 303. These steps may be repeated similarly in the case of forming additional circuitry layers on the second conductive layer 302.

As in the first embodiment stated above, the contact 303 of this embodiment extends no further than the N-type diffusion layer 306 and does not connect to the silicon substrate 309 even in the case of the contact 303 being out of alignment from the first conductive layer 301.

Further, because as in the first embodiment stated above, the first conductive layer 301 is inherently connected to the charge up prevention N-type diffusion layer 306 when formed, charge up prior to the step forming the second conductive layer 302 can be prevented.

In addition, as compared to the first embodiment, this embodiment does not require a second contact (204). Due to a single contact 303 sharing (combining) the first contact 203 and the second contact 204 of the first embodiment, a further reduction of surface area is possible.

What is claimed is:

1. A semiconductor device, comprising:
a semiconductor substrate;
a diffusion layer formed about a surface of the semiconductor substrate;
a first conductive layer formed on the semiconductor substrate;
an insulating layer formed on the semiconductor substrate after the first conductive layer and the diffusion layer are formed;
a second conductive layer formed on the insulating layer;
a first contact formed in the insulating layer, connecting the first conductive layer and the second conductive layer, and
a second contact formed in the insulating layer, connecting the first conductive layer and the diffusion layer; wherein
a part of the diffusion layer extends to a lower portion of the first contact.

2. The semiconductor device according to claim 1, further comprising:
a cell region including a predetermined function, and
an device isolating region formed about a surface of the semiconductor substrate; wherein
the device isolating region insulates the diffusion layer from the cell region; and
the first conductive layer extends from the cell region across the device isolating region.

3. The semiconductor device according to claim 1, wherein
the diffusion layer has a conduction type differing from a conduction type of the semiconductor substrate.

4. A semiconductor device, comprising:
a semiconductor substrate;
a diffusion layer formed about a surface of the semiconductor substrate;
a first conductive layer formed on the semiconductor substrate;
an insulating layer formed on the semiconductor substrate after the first conductive layer and the diffusion layer are formed;
a second conductive layer formed on the insulating layer; and
a contact formed in the insulating layer, connecting the first conductive layer to the second conductive layer and also connecting the second conductive layer to the diffusion layer.

5. The semiconductor device according to claim 3, wherein
a part of the diffusion layer extends to a lower portion of the contact.

6. The semiconductor device according to claim 4, further comprising:
a cell region including a predetermined function, and
an device isolating region formed about a surface of the semiconductor substrate; wherein
the device isolating region insulates the diffusion layer from the cell region, and
the first conductive layer extends from the cell region across the device isolating region.

7. The semiconductor device according to claim 4, wherein
a diameter of the contact is 5/3 or more of the width of the first conductive layer.

8. The semiconductor device according to claim 4, wherein
the diffusion layer has a conduction type differing from a conduction type of the semiconductor substrate.
